(19) United States
(12) Patent Application Publication
(10) Pub. No.: US 2009/0246918 A1
(43) Pub. Date: Oct. 1, 2009

(54) METHOD OF MANUFACTURING SEMICONDUCTOR DEVICE

(75) Inventors: Hiroshi NORO, Ibaraki-shi (JP); Yuusaku SHIMIZU, Ibaraki-shi (JP); Katsumi SHIMADA, Ibaraki-shi (JP); Daisuke TSUKAHARA, Ibaraki-shi (JP)

Correspondence Address: SUGHRUE-265550, 2100 PENNSYLVANIA AVE. NW, WASHINGTON, DC, 20037-3213, US

(73) Assignee: NITTO DENKO CORPORATION, Ibaraki-shi (JP)

(21) Appl. No.: 12/414,178

(22) Filed: Mar. 30, 2009

(30) Foreign Application Priority Data
Apr. 1, 2008 (JP) 2008-095345

(51) Int. Cl. H01L 21/56

(52) U.S. Cl. 438/127; 257/E21.502

(57) ABSTRACT

The present invention provides a method of manufacturing a semiconductor device in which a semiconductor element is mounted on a wiring circuit board and a clearance between the wiring circuit board and the semiconductor element is sealed with a sealing material, the method including: a sealing material arranging step of arranging the sealing material on at least one of a terminal-provided surface of the semiconductor element and a terminal-provided surface of the wiring circuit board; a sealing step of pressing the semiconductor element to the wiring circuit board under such a condition that a terminal of the semiconductor element and a terminal of the wiring circuit board are opposed with each other via the sealing material at a reduced pressure of 13300 Pa (absolute pressure) or less, thereby combining the semiconductor element with the wiring circuit board; and subsequent to the sealing step, a terminal connecting step of heating and fusing at least one of the terminal of the semiconductor element and the terminal of the wiring circuit board at an atmospheric pressure, thereby connecting the terminal of the semiconductor element and the terminal of the wiring circuit board.

### FIELD OF THE INVENTION

The present invention relates to a method of manufacturing a semiconductor device, which includes mounting a semiconductor element on a wiring circuit board.

### BACKGROUND OF THE INVENTION

In recent years, a size reduction, a thickness reduction, and a higher functionality of the semiconductor device have been progressed. With the progress of them, a size reduction, a thickness reduction, and a higher packaging density of semiconductor elements have been also required of the semiconductor device that is incorporated into the semiconductor device. As the semiconductor device responding to this demand, there is a flip-chip type semiconductor device.

This flip-chip type semiconductor device is manufactured as follows. That is, firstly, bumps (protruded terminals) are formed on one surface of a semiconductor element. Then, the bumps of the semiconductor element are aligned with the terminals formed on a wiring circuit board, and then the semiconductor element is mounted on the wiring circuit board. Then, the bumps of the semiconductor element are heated and fused, and connected to the terminals of the wiring circuit board. Then, a liquid insulating resin is filled in a clearance between the semiconductor element and the wiring circuit board by utilizing a capillary phenomenon. Then, the resin is cured to seal the clearance. This resin sealing protects connected portions of the bumps and the terminals from moisture, dusts (conductive substance), and the like and secures reliability of the semiconductor device.

Because the clearance is narrow, it takes much time to fill the liquid resin into the clearance. Therefore, as the resin sealing method that does not need this filling time, there has been proposed a method in which a resin sheet is arranged in advance on a bump-provided surface of the semiconductor element or a terminal-provided surface of the wiring circuit board and then the semiconductor element is mounted on the wiring circuit board via the resin sheet. After this, the semiconductor element is connected to the wiring circuit board via the terminals by the same way as above (see JP-A-2005-28734). According to this method, the resin sealing can be carried out simultaneously with the mounting of the semiconductor element on the wiring circuit board, so that a manufacturing time of the semiconductor device can be shortened.

However, in the above-mentioned method of filling the liquid resin into the clearance between the semiconductor element and the wiring circuit board, it is difficult to fill the resin perfectly because the clearance is narrow, and thus unfilled portions are easily caused. When the resin is cured while the unfilled portions are present as they are, the unfilled portions remain as voids (bubbles) in the cured resin. It is feared that, when the semiconductor device is energized to generate a heat, the voids expand and burst. When the voids burst, a function of the resin sealing (protection of the connected portions of the bumps) may be lowered, the connected portions of the bumps may be disconnected, the semiconductor element may be damaged, or the like, so that reliability of the semiconductor device may be impaired.

Similarly, in the method set forth in JP-A-2005-28734, the semiconductor element is aligned with the wiring circuit board via the resin sheet under such a condition that the resin sheet is arranged in advance on the terminal-provided surface of the semiconductor element or the terminal-provided surface of the wiring circuit board. Therefore, it is feared that an air is taken in their boundary during the alignment. The air that is taken in their boundary also remains as the voids. As a result, the similar problem to the above arises, so that reliability of the semiconductor device may be impaired.

The present invention has been made in view of such circumstances, and it is an object of the present invention to provide a method of manufacturing a semiconductor device, which creates no void in a sealing portion between a semiconductor element and a wiring circuit board and is capable of manufacturing a semiconductor device with good efficiency.

### SUMMARY OF THE INVENTION

In order to achieve the above object, the present invention provides a method of manufacturing a semiconductor device in which a semiconductor element is mounted on a wiring circuit board and a clearance between the wiring circuit board and the semiconductor element is sealed with a sealing material, the method including: a sealing material arranging step of arranging the sealing material on at least one of a terminal-provided surface of the semiconductor element and a terminal-provided surface of the wiring circuit board; a sealing step of pressing the semiconductor element to the wiring circuit board under such a condition that a terminal of the semiconductor element and a terminal of the wiring circuit board are opposed with each other via the sealing material at a reduced pressure of 13300 Pa (absolute pressure) or less, thereby combining the semiconductor element with the wiring circuit board; and subsequent to the sealing step, a terminal connecting step of heating and fusing at least one of the terminal of the semiconductor element and the terminal of the wiring circuit board at an atmospheric pressure, thereby connecting the terminal of the semiconductor element and the terminal of the wiring circuit board.

In the method of manufacturing a semiconductor device of the present invention, the sealing material is arranged on at least one of the terminal-provided surface of the semiconductor element and the terminal-provided surface of the wiring circuit board, and then the semiconductor element is pressed to the wiring circuit board via the sealing material, thereby being combined together. Therefore, the combine of the semiconductor element and the wiring circuit board and the sealing of the terminals by the sealing material can be executed at a time. Accordingly, a semiconductor device can be manufactured effectively. In addition, since the combine is conducted at a reduced pressure of 13300 Pa (absolute pressure) or less, an air is never taken in at the time of the combine. Furthermore, since the terminal connecting step is conducted by heating and fusing at least one of the terminal of the wiring circuit board and the terminal of the semiconductor element at an atmospheric pressure, the air is never produced inside the sealing material. That is, when the terminal connecting step is conducted at a reduced pressure (a pressure lower than an atmospheric pressure), a boiling point of a resin component of low molecular weight contained in the sealing material is lowered and the resin component of low molecular weight is boiled during the heating to fuse the terminals, whereby the air is vaporized from the inside of the sealing material (the gas is produced). However, according to the present invention, since the terminal connecting step is conducted at an atmospheric pressure, neither a boiling point of a resin component of low molecular weight contained in the sealing material is lowered nor the air is vaporized from the inside of the sealing material (the gas is not produced). That is, no void is produced in the sealing material owing to the combination of the sealing step conducted at a reduced pressure of 13300 Pa (absolute pressure) or less and the terminal connecting step conducted at an atmospheric pressure.

### BRIEF DESCRIPTION OF THE DRAWINGS

FIGS. 1A to 1D are explanatory views showing schematically an embodiment of a sealing material arranging step in a method of manufacturing a semiconductor device of the present invention.

FIGS. 2A to 2D are explanatory views showing schematically an embodiment of a sealing step in the method of manufacturing a semiconductor device of the present invention.

FIGS. 3A and 3B are explanatory views showing schematically an embodiment of a terminal connecting step in the method of manufacturing a semiconductor device of the present invention.

FIG. 4A to 4C are explanatory views showing schematically a terminal connecting step in a method of manufacturing a semiconductor device of Comparative Examples 1 and 2.

FIG. 5A to 5C are explanatory views showing schematically a sealing step in the method of manufacturing a semiconductor device of Comparative Example 2.

### DESCRIPTION OF REFERENCE NUMERALS AND SIGNS

2 sealing material
3 semiconductor element
5 wiring circuit board
3a, 5a terminal

### DETAILED DESCRIPTION OF THE INVENTION

Next, an embodiment of the present invention will be explained in detail with reference to the drawings hereinafter.

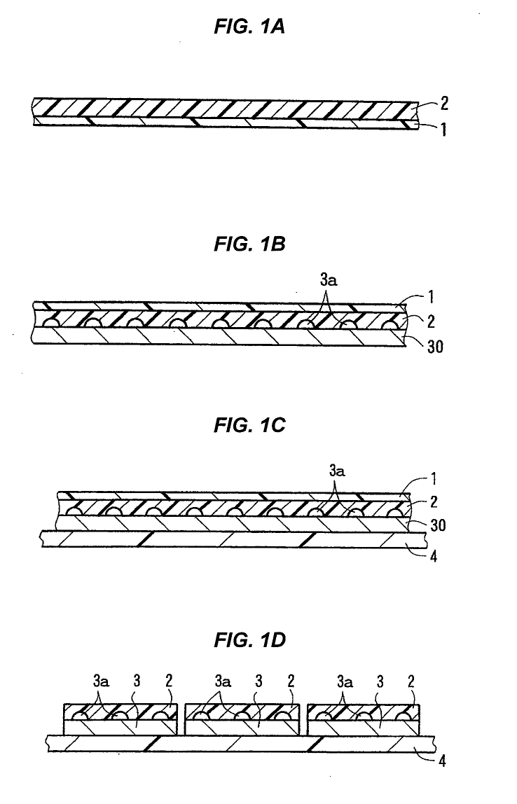

FIGS. 1A to 1D, FIGS. 2A to 2D, and FIGS. 3A and 3B show schematically an embodiment of a method of manufacturing a semiconductor device of the present invention. In this embodiment, following steps (1) to (3) are provided.

(1) A sealing material arranging step in which a sealing material 2 is arranged on a terminal-provided surface of a semiconductor element 3 (see FIGS. 1A to 1D).

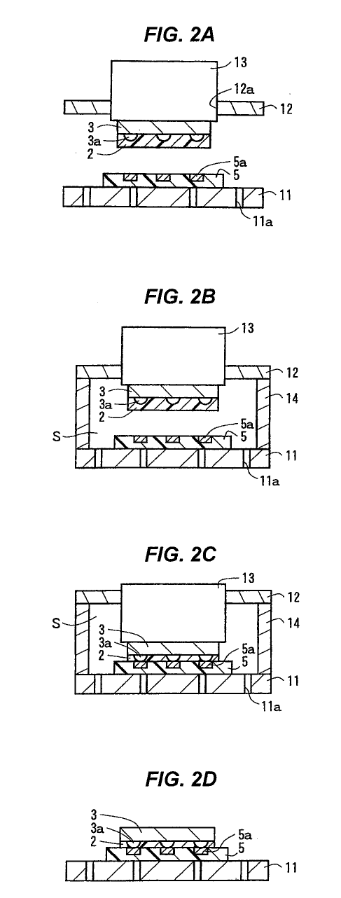

(2) A sealing step in which the semiconductor element 3 is pressed to a wiring circuit board 5 under such a condition that the terminals 3a of the semiconductor element 3 and terminals 5a of the wiring circuit board 5 are opposed with each other via the sealing material 2 at an atmospheric pressure of 13300 Pa (absolute pressure) or less, thereby combining the wiring circuit board 5 and the semiconductor element 3 (see FIGS. 2A to 2D).

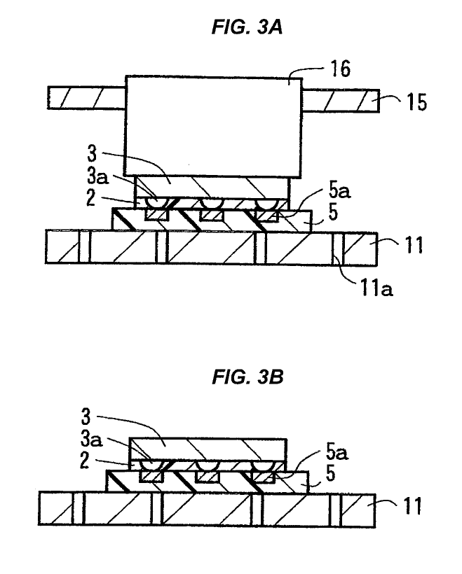

(3) A terminal connecting step of heating and fusing the terminals 3a of the semiconductor element 3 at an atmospheric pressure, thereby connecting the terminals 3a of the semiconductor element 3 and terminals 5a of the wiring circuit board 5 (see FIGS. 3A and 3B).

More specifically explaining, the sealing material arranging step (1) above is a step of arranging the sealing material 2 on the terminal-provided surface of the semiconductor element 3, for example, as follows.

First, as shown in FIG. 1A, a liquid material (such as an epoxy resin) of the sealing material 2 is coated on a release sheet 1 such as a PET (polyethylene terephthalate) film by a spin coating, a printing method, or the like, followed by drying, thereby forming the sealing material 2.

A wafer 30 in which a plurality of portions each being to be served as a semiconductor element 3 (see FIG. 1D) are formed and the terminals 3a are provided to each portion to be served as a semiconductor element 3 is prepared (see FIG. 1B). Then, as shown in FIG. 1B, the sealing material 2 is attached onto the terminal-provided surface of the wafer 30. In this attached state, a surface of the sealing material 2 is brought into intimate contact with the terminal-provided surface of the wafer 30, so that the terminals 3a of the wafer 30 are embedded in the sealing material 2. A roller pasting machine, or the like is employed in the attaching. Also, from the viewpoint of improving adhesion between the terminal-provided surface of the wafer 30 and the sealing material 2, a temperature in the attaching is set in a range of about 40° C. to 80° C.

Then, as shown in FIG. 1C, the wafer 30 side of the wafer 30 provided with the sealing material 2 is attached to a dicing tape 4.

Then, as shown in FIG. 1D, the release sheet 1 is released, and then the wafer 30 is cut into respective semiconductor elements 3 using a dicing machine. This cutting is applied from the sealing material 2 side, and the dicing tape 4 is not cut. In this manner, the sealing material arranging step in (1) is completed, whereby the semiconductor element 3 provided with the sealing material 2 is obtained.

The sealing step (2) above subsequent to the sealing material arranging step (1) above is a step in which the sealing using the sealing material 2 is carried out, for example, as follows.

First, the wiring circuit board 5 equipped with the terminals 5a is prepared.

Then, as shown in FIG. 2A, the wiring circuit board 5 is put on a surface of a suction stage 11 in which suction holes 11a are formed. At this time, the wiring circuit board 5 is put on the suction stage 11 such that a surface of the wiring circuit board 5 opposite to the terminal-provided surface thereof comes into contact with the surface of the suction stage 11. Also, each semiconductor element 3 provided with the sealing material 2 obtained in the above sealing material arranging step is picked up from the dicing tape 4 (see FIG. 1D) and is removed therefrom. Then, the semiconductor element 3 side is fitted to a bonding head 13. Then, the terminals 3a of the semiconductor element 3 are put to oppose to the terminals 5a of the wiring circuit board 5 via the sealing material 2. In this case, the bonding head 13 is fitted vertically slidably into a hole 12a, which is provided in a collet 12, in a hermetic state.

In this state, as shown in FIG. 2B, an area between a lower surface of the collet 12 and the surface of the suction stage 11 is hermetically sealed with a sealing material 14 made of a heat resistant silicon rubber or the like to surround the wiring circuit board 5. Then, an air is degassed through the suction hole 11a of the suction stage 11. Thus, the wiring circuit board 5 is sucked/fixed to the surface of the suction stage 11, as well as an atmospheric pressure in a sealed space S, which is sealed with the lower surface of the collet 12, the surface of the suction stage 11 and the sealing material 14, is lowered to 13300 Pa (absolute pressure) or less.

Then, as shown in FIG. 2C, the semiconductor element 3 is pressed to the wiring circuit board 5 by bringing down the bonding head 13 while keeping the sealed space S in a reduced pressure state. Accordingly, the semiconductor element 3 is adhered to the wiring circuit board 5 via the sealing material 2 to be combined together, and simultaneously a space between the semiconductor element 3 and the wiring circuit board 5 is sealed with the sealing material 2. At this time, because a reduced pressure state is kept, no air is taken in the space between the sealing material 2 and the wiring circuit board 5. In this case, from the viewpoint of improving adhesiveness and a sealing performance between the semiconductor element 3 and the wiring circuit board 5, the pressing conditions are set such that a pressing load is set in a range of about 10 N to 50 N, a temperature in the pressing is set in a range of about 80° C. to 160° C. (at which the sealing material 2 is softened or melted), and a pushing time is set in a range of about 0.5 sec to 5 sec.

Then, as shown in FIG. 2D, the pressing state is released by bringing up the bonding head 13, and also the reduced pressure state is released (to be an atmospheric pressure) by removing the collet 12 and the sealing material 14. In this manner, the sealing step (2) above is completed.

The terminal connecting step (3) above subsequent to the sealing step (2) above is a step of connecting the terminals 3a and the terminals 5a, for example, as follows.

First, as shown in FIG. 3A, the semiconductor element 3 is pressed to the wiring circuit board 5 by a bonding head 16 of a new collet 15 that is different from the collet 12 (see FIG. 2A), and is heated. At this time, the wiring circuit board 5 is sucked/fixed to the surface of the suction stage 11, and the surrounding pressure is set to an atmospheric pressure. Accordingly, the terminals 3a of the semiconductor element 3 are fused and connected to the terminals 5a of the wiring circuit board 5. In this manner, a semiconductor device in which the semiconductor element 3 is mounted on the wiring circuit board 5 is obtained. The pressing operation is applied not only to inhibit the displacement of both the terminals 3a and the terminals 5a, but also to transfer a heat given by the heating without fail. Therefore, as the pressing conditions, a pressing load is set in a range of about 4 N to 6 N, a temperature in the pressing is set in a range of about 240° C. to 280° C., and a pressing time is set in a range of about 15 sec to 25 sec.

Then, as shown in FIG. 3B, the pressing is released by bringing up the bonding head 16, and the collet 15 is removed. Also, the sucking operation of the suction stage 11 is released. Then, the semiconductor device thus manufactured is picked up from the surface of the suction stage 11. In this manner, the terminal connecting step (3) above is completed, and the intended semiconductor device is obtained.

In the method of manufacturing a semiconductor device, combine of the semiconductor element 3 and the wiring circuit board 5 and sealing by the sealing material 2 can be executed at a time. Therefore, this manufacturing method is excellent in productivity of a semiconductor device. In addition, since the above-mentioned combine is executed at a reduced pressure of 13300 Pa (absolute pressure) or less, an air is never taken in the boundary between the semiconductor element 3 and the wiring circuit board 5 at the time of the combine. Furthermore, since the subsequent heating and fusing of the terminals 3a is conducted at an atmospheric pressure, neither a boiling point of a resin component of low molecular weight contained in the sealing material 2 is lowered nor the resin component of low molecular weight is boiled during the heating/fusing of the terminals 3a. As a result, no void is produced in the sealing material 2 of the resultant semiconductor device.

Here, the material, etc. employed in the method of manufacturing a semiconductor device will be explained hereunder.

As a principal component of the liquid material of the sealing material 2 that seals the clearance between the semiconductor element 3 and the wiring circuit board 5, for example, acrylic resin, polyimide resin, benzocyclobutene, and the like may be mentioned in addition to the above-mentioned epoxy resin. From the viewpoints of adhesiveness, fluidity, and moisture resistant reliability, it is preferable that epoxy resin be used as a principal component out of them. Here, the “principal component” denotes a component that occupies the greater part of the overall components.

As the constituting material of the sealing material 14 that hermetically seals the clearance between the lower surface of the collet 12 and the surface of the suction stage 11 in the sealing step in (2), urethane rubber, nitrile rubber, chloroprene rubber, and the like may be mentioned in addition to the above-mentioned heat resistant silicon rubber. Also, a height of the sealing material 14 (a clearance between the lower surface of the collet 12 and the surface of the suction stage 11) may be set to any dimension if such height exceeds a height of the semiconductor device to be manufactured. For example, such height of the sealing material 14 may be set in a range of 0.1 to 4.0 mm.

As the constituting material of the semiconductor element 3 (the wafer 30), for example, silicon, gallium arsenide, and the like may be mentioned. Also, as the constituting material of the terminals (bumps) 3a formed on the semiconductor element 3, solder bump (low-melting bump or refractory bump), tin bump, silver-tin bump, silver-tin-copper bump, gold bump, copper bump, and the like may be mentioned. From the viewpoint of connection reliability, it is preferable that solder bump be employed out of them. Normally a fusing temperature of the terminals 3a of the semiconductor element 3 is within a range of 180° C. to 230° C.

As the wiring circuit board 5, ceramic substrate and plastic substrate may be mentioned when classified roughly. As the plastic substrate, for example, epoxy substrate, bismaleimidetriazine substrate, polyimide substrate, and the like may be mentioned. As the constituting material of the wiring circuit and the terminals 5a that are formed on the substrate, for example, copper, and the like may be considered. In particular, it is preferable that a gold plating be applied to the surface of the terminals 5a.

In accordance with the above embodiment, in the sealing material arranging step (1) above, a liquid material is used to form the sealing material 2, the sealing material 2 is formed on the release sheet 1 by drying the liquid material, and the sealing material 2 is attached onto the terminal-provided surface of the wafer 30 (the semiconductor element 3). However, other approaches may be applied. For example, a seat-like sealing material 2 may be prepared in advance, and then this sealing material 2 may be attached onto the terminal-provided surface of the wafer 30 by roller lamination, press bonding, or the like. As still another example, the liquid material of the sealing material 2 may be coated directly on the terminal-provided surface of the wafer 30. In this case, in the sealing step (2) above, there is no need to increase a temperature at a time of the pressing when the semiconductor element 3 is pressed to the wiring circuit board 5 to be combined together (see FIG. 2C).

Also, in accordance with the above embodiment, in the sealing material arranging step (1) above, the sealing material 2 is arranged on the terminal-provided surface of the semiconductor element 3. However, the sealing material 2 may be arranged on the terminal-provided surface of the wiring circuit board 5, or may be arranged on both terminal-provided surfaces.

Also, in accordance with the above embodiment, in the sealing step (2) above and the terminal connecting step (3) above, the pressing, etc. are executed by using the different collets 12 and 15 and the different bonding heads 13 and 16, respectively. However, the same collet or the same bonding head may be used.

Also, in accordance with the above embodiment, in the terminal connecting step (3) above, the terminals 3a of the semiconductor element 3 are fused. However, the terminals 5a of the wiring circuit board 5 may be fused or both terminals 3a and 5a may be fused.

Furthermore, in accordance with the above embodiment, although a plurality of terminals 3a have been provided on the semiconductor element 3, the number of the terminals 3a is not particularly limited, and it may be one or may be two or more. Additionally, although a plurality of terminals 5a have been provided on the wiring circuit board 5, the number of the terminals 5a is not particularly limited, and it may be one or may be two or more.

Next, respective examples will be explained together with comparative examples and a conventional example hereunder. However, the present invention is not restricted to these examples.

### EXAMPLES

### Examples 1 to 7

### Comparative Examples 1 to 3, and Conventional Example 1

(Liquid Material of Sealing Material)

25 g of epoxy resin (manufactured by DIC Corporation, HP-4032D), 19 g of phenol resin (manufactured by Arakawa Chemical Industries, Ltd., P-180), 7.8 g of alkylester copolymer (Mooney viscosity ML (1+4), 100° C.: 52.5), and 1.6 g of 1, 9-nonanedicarboxylic acid were mixed into a methyl ethyl ketone and melted therein. Then, 0.5 g of accelerator (manufactured by Hokko Chemical Industry Co., Ltd., TPPK) was added in this mixed solution, and the resultant solution was stirred at 3000 rpm for 10 minute by using the homodisper. In this manner, the liquid material of the sealing material was prepared.

(Formation of Sealing Material Layer)

A liquid material of the sealing material was coated on a PET film (release sheet), which has been subjected to release treatment, by spin coating. Then, the resultant layer was dried at 120° C. for 10 minute, thereby removing methyl ethyl ketone. Accordingly, the sealing material layer having a thickness of 80 μm was formed on the PET film.

(Manufacture of Semiconductor Element Provided with Sealing Material)

The sealing material layer was attached onto the terminal-provided surface of the silicon wafer on which a plurality of semiconductor elements are aligned and formed (wiring: aluminum, terminal: silver-tin-copper solder (melting point 218° C.), electrode outer diameter: 100 μm, electrode height: 80 μm) at 70° C. by using a roller pasting machine (manufactured by Nitto Denko Corporation, DR-8500-II). Then, the wafer side of the wafer provided with the sealing material layer was attached onto the dicing tape (manufactured by Nitto Denko Corporation, DU-300). Then, the PET film was released, and then the wafer was cut into respective semiconductor elements (10 mm×10 mm) by using a dicing machine (manufactured by DISCO Corporation, DFD-651), whereby a semiconductor element provided with the sealing material was obtained.

(Manufacture of Semiconductor Device)

Respective semiconductor elements provided with the sealing material were picked up from the dicing tape, and were removed. Then, the semiconductor element side thereof was fitted to a bonding head of a flip-chip bonder (manufactured by Shibuya Kogyo Co., Ltd., DB-100). Then, the semiconductor element was mounted (combined and sealed) on the wiring circuit board made of plastics (substrate material: FR-4, wiring: copper, terminal surface: gold flash plating) under conditions given in Tables 1 and 2 described later, and then reflow soldering (terminal connection) was applied. Thus, the semiconductor device was obtained.

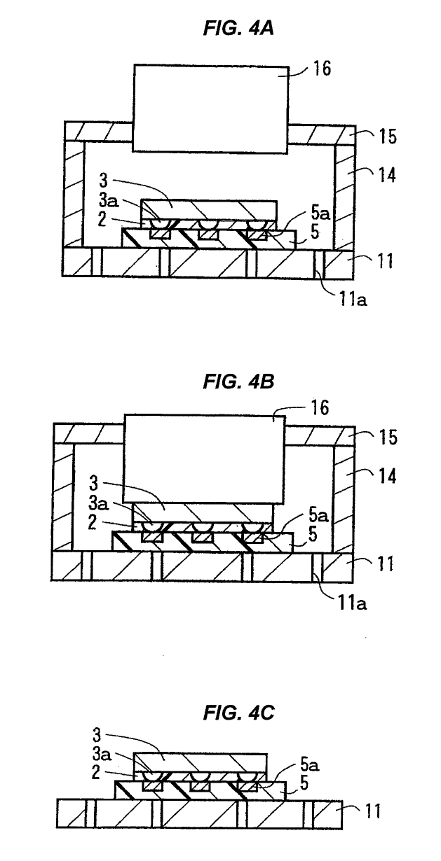

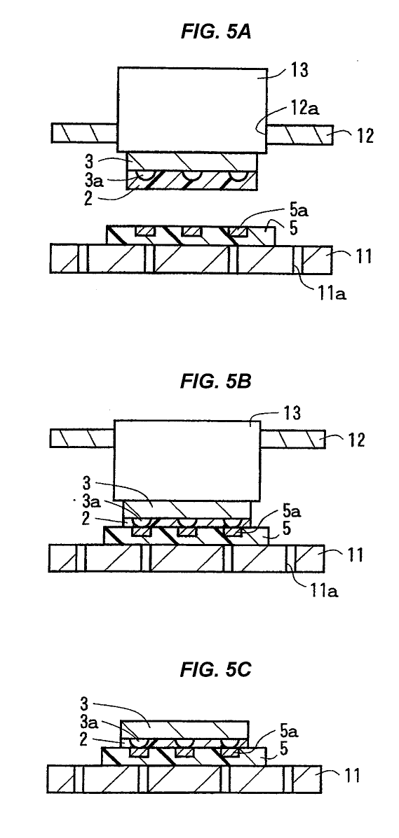

In this event, in Tables 1 and 2 described later, in Comparative Example 1, the mounting of the semiconductor element was conducted at a reduced pressure in the similar step to that in Examples 1 to 7 (see FIGS. 2A to 2D), and the reflow soldering was applied at a reduced pressure in the similar step to those in FIGS. 2B to 2D, as shown in FIGS. 4A to 4C. In Comparative Example 2, the mounting of the semiconductor element was conducted at an atmospheric pressure, as shown in FIGS. 5A to 5C, and the reflow soldering was applied at a reduced pressure in the similar step to that in Comparative Example 1 (see FIGS. 4A to 4C). In Comparative Example 3, both the mounting of the semiconductor element and the reflow soldering were conducted in the similar step to those in Examples 1 to 7 (see FIGS. 2A to 2D and FIGS. 3A and 3B). In Conventional Example 1, the mounting of the semiconductor element was conducted at an atmospheric pressure in the similar step to that in Comparative Example 2 (see FIGS. 5A to 5C), and the reflow soldering was applied at an atmospheric pressure in the similar step to those in Examples 1 to 7 (see FIGS. 2A to 2D). Here, in FIGS. 4A to 4C and FIGS. 5A to 5C, the same reference symbols are affixed to the similar parts to those in FIGS. 2A to 2D and FIGS. 3A and 3B.

(Presence or Absence of Void)

The sealing portions of the semiconductor devices obtained in this manner were observed by the ultrasonic microscope (manufactured by Hitachi Construction Machinery Co., Ltd., frequency 130 MHz) respectively to check whether or not the void was produced. The results are given in Tables 1 and 2.

(Terminal Connectivity)

The electric resistance values given by the daisy chain provided on the semiconductor element and the wiring circuit board of the semiconductor device were measured. Thus, it was checked whether or not respective terminals are connected. The results are also given in Tables 1 and 2.

TABLE 1

| Examples | | | | | | |
|---|---|---|---|---|---|---|
| 1 | 2 | 3 | 4 | 5 | 6 | 7 |

| | | | | |
|---|---|---|---|---|
| Mount | Temperature (° C.) | 140 | 100 | 140 |

| | | | | |
|---|---|---|---|---|
| condition | Load (N) | 39.2 | 19.6 | 39.2 |

| | | | |
|---|---|---|---|
| Time (sec) | 3 | 1 | 3 |

| | | | | | |
|---|---|---|---|---|---|
| Pressure (Pa) | 133 | 3990 | 11970 | 133 | 13300 |

| | | |
|---|---|---|
| Reflow | Temperature (° C.) | 260 |
| condition | Load (N) | 4.9 |
| | Time (sec) | 20 |
| | Pressure (Pa) | 101300 |

| | |
|---|---|
| Presence of void | No |
| Terminal connectivity | Connected |

Pressure (Pa): absolute pressure

TABLE 2

| | | | | | Conven- |
|---|---|---|---|---|---|
| | | Comparative | | | tional |
| | | Example | | | Example |
| | | 1 | 2 | 3 | 1 |
| Mount | Temperature | 140 | | | |
| condition | (° C.) | | | | |
| | Load (N) | 39.2 | | | |
| | Time (sec) | 3 | | | |
| | Pressure (Pa) | 133 | 101300 | 15000 | 101300 |

| Reflow | Temperature | 260 | |
|---|---|---|---|
| condition | (° C.) | | |
| | Load (N) | 4.9 | |
| | Time (sec) | 20 | |
| | Pressure (Pa) | 133 | 101300 |

| Presence of void | Yes | | |
|---|---|---|---|
| Terminal connectivity | Connected | Unconnected | Connected |

Pressure (Pa): absolute pressure

From the results in Tables 1 and 2, it was found that, in the semiconductor devices in Examples 1 to 7, the sealing material had no void and all terminals were connected. In contrast, in Comparative Example 1, since the semiconductor element was mounted on the wiring circuit board at a proper reduced pressure but the subsequent reflow soldering was also conducted at a reduced pressure, a boiling point of the resin component of low molecular weight contained in the sealing material was lowered, and also the resin component of low molecular weight was boiled by the heating in the reflow soldering (a gas was produced from the inside of the sealing material). Therefore, in the semiconductor device in Comparative Example 1, the gas still remained as the void in the sealing material. Also, in Comparative Example 2, since the semiconductor element was mounted on the wiring circuit board at an atmospheric pressure, an air was taken in during the mounting. Also, the air was not sufficiently degassed by the reflow soldering applied thereafter at a reduced pressure. Therefore, in the semiconductor device in Comparative Example 2, the air still remained as the voids in the sealing material. In addition, in Comparative Example 2, the voids moved in the sealing material during the reflow soldering, and the fused solder (the terminals of the semiconductor element) flowed correspondingly. Consequently, some terminals were not connected. Also, in Comparative Example 3, the semiconductor element was mounted on the wiring circuit board at a reduced pressure, but a pressure reduction at a time of mounting the semiconductor element is insufficient. Thus, the air was taken in during the mounting. Therefore, in the semiconductor device in Comparative Example 3, the air still remained as the voids in the sealing material. Also, in Conventional Example 1, since the semiconductor element was mounted on the wiring circuit board at an atmospheric pressure, the air was taken in during the mounting. Therefore, in the semiconductor device in Conventional Example 1, the air still remained as the voids in the sealing material.

While the present invention has been described in detail and with reference to specific embodiments thereof, it will be apparent to one skilled in the art that various changes and modifications can be made therein without departing from the scope thereof.

This application is based on Japanese patent application No. 2008-095345 filed Apr. 1, 2008, the entire contents thereof being hereby incorporated by reference.

What is claimed is:

1. A method of manufacturing a semiconductor device in which a semiconductor element is mounted on a wiring circuit board and a clearance between the wiring circuit board and the semiconductor element is sealed with a sealing material, said method comprising:
a sealing material arranging step of arranging the sealing material on at least one of a terminal-provided surface of the semiconductor element and a terminal-provided surface of the wiring circuit board;
a sealing step of pressing the semiconductor element to the wiring circuit board under such a condition that a terminal of the semiconductor element and a terminal of the wiring circuit board are opposed with each other via the sealing material at a reduced pressure of 13300 Pa (absolute pressure) or less, thereby combining the semiconductor element with the wiring circuit board; and
subsequent to the sealing step, a terminal connecting step of heating and fusing at least one of the terminal of the semiconductor element and the terminal of the wiring circuit board at an atmospheric pressure, thereby connecting the terminal of the semiconductor element and the terminal of the wiring circuit board.

2. The method according to claim 1, wherein the terminal of the semiconductor element comprises a solder bump.

3. The method according to claim 1, wherein the sealing material is a sheet-like sealing material.

4. The method according to claim 2, wherein the sealing material is a sheet-like sealing material.
